(19) United States
(12) Patent Application Publication
(10) Pub. No.: US 2025/0169143 A1
(43) Pub. Date: May 22, 2025

(54) INSULATED GATE BIPOLAR TRANSISTOR

(71) Applicant: DENSO CORPORATION, Kariya-city (JP)

(72) Inventor: Takaya NAGAI, Kariya-city (JP)

(21) Appl. No.: 19/030,438

(22) Filed: Jan. 17, 2025

Related U.S. Application Data
(63) Continuation of application No. PCT/JP2023/017802, filed on May 11, 2023.

(30) Foreign Application Priority Data
Aug. 5, 2022 (JP) 2022-125751

(51) Int. Cl. H10D 64/23; H10D 12/00; H10D 64/00

(52) U.S. Cl. CPC H10D 64/232; H10D 12/481; H10D 64/117

(57) ABSTRACT

An insulated gate bipolar transistor has: a first active area, a second active area, and a non-active area between the first active area and the second active area. Dummy trenches are disposed in the non-active area. An inter-trench region is disposed in a hole accumulation region between a first boundary gate trench and a second boundary gate trench, so as to satisfy following conditions: plural non-contact inter-trench regions are arranged in the non-active area; at least one contact inter-trench region is arranged in the non-active area; and the non-contact inter-trench regions are not adjacent to each other in the hole accumulation region.

### CROSS REFERENCE TO RELATED APPLICATIONS

The present application is a continuation application of International Patent Application No. PCT/JP2023/017802 filed on May 11, 2023, which designated the U.S. and claims the benefit of priority from Japanese Patent Application No. 2022-125751 filed on Aug. 5, 2022. The entire disclosures of all of the above applications are incorporated herein by reference.

### TECHNICAL FIELD

The present disclosure relates to an insulated gate bipolar transistor.

### BACKGROUND

In an insulated gate bipolar transistor (hereinafter referred to as IGBT), trenches are provided in a surface of a semiconductor substrate. A gate electrode or a dummy electrode is provided in each of the trenches. The gate electrode has a potential independent of the emitter electrode. The dummy electrode has a potential independent of the gate electrode. In an active area where the gate electrode is provided, a channel is formed in the base layer when a predetermined potential is applied to the gate electrode.

### SUMMARY

According to an aspect of the present disclosure, an insulated gate bipolar transistor includes: a semiconductor substrate having trenches spaced from each other on an upper surface; an emitter electrode on the upper surface of the semiconductor substrate; a collector electrode on the lower surface of the semiconductor substrate; a gate insulating film covering the inner surface of the trench; and a trench electrode disposed in each of the trenches and insulated from the semiconductor substrate by the gate insulating film. The trenches include a gate trench and a dummy trench. The trench electrode in the gate trench is a gate electrode having a potential independent of the emitter electrode. The trench electrode in the dummy trench is a dummy electrode having a potential independent of the gate electrode.

The semiconductor substrate has a first active area in which the gate trenches are arranged, a second active area in which the gate trenches are arranged, and a non-active area arranged between the first active area and the second active area, in which the dummy trenches are arranged. The semiconductor substrate has a collector layer, a drift layer, a base layer and emitter layers. The collector layer is a p-type layer that is distributed across the first active area, the second active area, and the non-active area and is in contact with the collector electrode. The drift layer is an n-type layer that is distributed across the first active area, the second active area, and the non-active area and is disposed on the collector layer. The base layer is a p-type layer distributed across the first active area, the second active area, and the non-active area, disposed on the drift layer, and disposed in inter-trench regions located between the trenches. The emitter layer is disposed in the inter-trench region of the first active area and the second active area, in contact with the gate insulating film, in contact with the emitter electrode, and n-type layer separated from the drift layer by the base layer. In the inter-trench regions of the first active area and the second active area, the base layer is in contact with the emitter electrode.

The inter-trench region is arranged in a hole accumulation region between a first boundary gate trench that is the closest to the non-active area among the gate trenches in the first active area and a second boundary gate trench that is the closest to the non-active area among the gate trenches in the second active area: so as to satisfy conditions of:
plural non-contact inter-trench regions are disposed within the non-active area, the non-contact inter-trench region being the inter-trench region in which the base layer is insulated from the emitter electrode;
at least one contact inter-trench region, which is the trench region in which the base layer is in contact with the emitter electrode, is disposed in the non-active area; and
the non-contact inter-trench regions are not adjacent to each other in the hole accumulation region.

### BRIEF DESCRIPTION OF DRAWINGS

FIG. 1 is a cross-sectional view of an IGBT according to an embodiment.

FIG. 2 is a cross-sectional view of an IGBT of a comparative example.

FIG. 3 is a graph showing a hole current density distribution of the IGBT of the embodiment.

FIG. 4 is a graph showing a hole current density distribution of the IGBT of the comparative example.

FIG. 5 is a graph showing a relationship between a peak of a hole current density and the number of contact inter-trench regions.

FIG. 6 is a cross-sectional view of an IGBT according to a first modification.

FIG. 7 is a cross-sectional view of an IGBT according to a second modification.

FIG. 8 is a cross-sectional view of an IGBT according to a third modification.

FIG. 9 is a cross-sectional view of an IGBT according to a fourth modification.

### DETAILED DESCRIPTION

In an insulated gate bipolar transistor (hereinafter referred to as IGBT), trenches are provided in a surface of a semiconductor substrate. A gate electrode or a dummy electrode is provided in each of the trenches. The gate electrode has a potential independent of the emitter electrode. The dummy electrode has a potential independent of the gate electrode. In an active area where the gate electrode is provided, a channel is formed in the base layer when a predetermined potential is applied to the gate electrode. The active area therefore functions as an IGBT. In a non-active area where the dummy electrode is provided, no channel is formed in the base layer. Therefore, the non-active area does not function as an IGBT. In the non-active area, the base layer is not connected to the emitter electrode.

When the IGBT is on, holes flow from the collector layer into the drift layer. The holes that have flowed into the drift layer flow to the emitter electrode via the base layer. Since the base layer is not connected to the emitter electrode in the non-active area, holes do not flow to the emitter electrode in the non-active area. For this reason, holes tend to accumulate in the drift layer of the IGBT. Therefore, the resistance of the drift layer is reduced by the so-called IE (injection enhanced) effect. Therefore, the on-voltage of this IGBT is low.

The holes stored in the drift layer while the IGBT is on flow to the emitter electrode via the base layer when the IGBT is turned off. As described above, in the IGBT, the base layer in the non-active area is not connected to the emitter electrode. Therefore, when the IGBT is turned off, holes present in the drift layer of the non-active area flow to the emitter electrode via the base layer of the active area adjacent to the non-active area (i.e., the base layer at the boundary). For this reason, hole current is concentrated in the base layer at the boundary, making latch-up likely to occur. This specification proposes an IGBT that provides the IE effect and is less susceptible to latch-up.

According to an aspect of the present disclosure, an insulated gate bipolar transistor includes: a semiconductor substrate having trenches spaced from each other on an upper surface; an emitter electrode formed on the upper surface of the semiconductor substrate; a collector electrode formed on the lower surface of the semiconductor substrate; a gate insulating film covering the inner surface of each of the trenches; and a trench electrode disposed in each of the trenches and insulated from the semiconductor substrate by the gate insulating film. The trenches include a gate trench and a dummy trench. The trench electrode in the gate trench is a gate electrode having a potential independent of the emitter electrode. The trench electrode in the dummy trench is a dummy electrode having a potential independent of the gate electrode.

The semiconductor substrate has a first active area in which the gate trenches are arranged, a second active area in which the gate trenches are arranged, and a non-active area arranged between the first active area and the second active area, in which the dummy trenches are arranged. The semiconductor substrate has a collector layer, a drift layer, a base layer and emitter layers. The collector layer is a p-type layer that is distributed across the first active area, the second active area, and the non-active area and is in contact with the collector electrode. The drift layer is an n-type layer that is distributed across the first active area, the second active area, and the non-active area and is disposed on the collector layer. The base layer is a p-type layer distributed across the first active area, the second active area, and the non-active area, disposed on the drift layer, and disposed in inter-trench regions located between the trenches. The emitter layers are disposed in the inter-trench regions in the first active area and the second active area, are in contact with the gate insulating film, are in contact with the emitter electrode, and are n-type layers separated from the drift layer by the base layer. In the inter-trench regions of the first active area and the second active area, the base layer is in contact with the emitter electrode.

The inter-trench regions are arranged in a hole accumulation region between a first boundary gate trench that is the closest to the non-active area among the gate trenches in the first active area and a second boundary gate trench that is the closest to the non-active area among the gate trenches in the second active area: so as to satisfy conditions of:
plural non-contact inter-trench regions are disposed within the non-active area, the non-contact inter-trench region being the inter-trench region in which the base layer is insulated from the emitter electrode;
at least one contact inter-trench region, which is the trench region in which the base layer is in contact with the emitter electrode, is disposed in the non-active area; and
the non-contact inter-trench regions are not adjacent to each other in the hole accumulation region.

The phrase “non-contact inter-trench regions are adjacent to each other” means that plural contact inter-trench regions are adjacent to each other via trench. In other words, the phrase “the non-contact inter-trench regions are not adjacent to each other in the hole accumulation region” means that there is no location within the hole accumulation region where multiple contact inter-trench regions are adjacent to each other with trench interposed therebetween.

When the IGBT is turned on, the non-contact inter-trench region arranged in the non-active area restricts holes in the drift layer from flowing to the emitter electrode. As a result, the resistance of the drift layer is reduced by the IE effect. Further, at least one contact inter-trench region is disposed within the non-active area such that the non-contact inter-trench regions are not adjacent to each other. Therefore, when the IGBT is turned off, the holes stored in the drift layer flow to the emitter electrode through the base layer in the contact inter-trench region of the non-active area. This suppresses the concentration of hole current in the base layer of the contact inter-trench region around the non-contact inter-trench region. This suppresses latch-up. As described above, this IGBT provides the IE effect and is less susceptible to latch-up.

In the IGBT, when the dummy trench adjacent to the first boundary gate trench is defined as a first boundary dummy trench, the inter-trench region between the first boundary gate trench and the first boundary dummy trench may be the contact inter-trench region, and the inter-trench region between the first boundary dummy trench and the dummy trench adjacent to each other may be the contact inter-trench region. Furthermore, when the dummy trench adjacent to the second boundary gate trench is defined as a second boundary dummy trench, the inter-trench region between the second boundary gate trench and the second boundary dummy trench may be the contact inter-trench region, and the inter-trench region between the second boundary dummy trench and the dummy trench adjacent to each other may be the contact inter-trench region.

The density of hole current tends to become high in the inter-trench region between the gate trench and the dummy trench. In contrast, as described above, by making the inter-trench region between the first boundary dummy trench and the dummy trench, and the inter-trench region between the second boundary dummy trench and the dummy trench into the contact inter-trench regions, it is possible to suppress the concentration of hole current in the inter-trench region between the gate trench and the dummy trench.

In the IGBT, the semiconductor substrate may have a barrier layer and a lower base layer. The barrier layer may be an n-type layer distributed across the first active area, the second active area, and the non-active area, disposed below the base layer, and disposed in each of the inter-trench regions. The lower base layer may be a p-type layer distributed across the first active area, the second active area, and the non-active area, disposed between the barrier layer and the drift layer, and disposed in each of the inter-trench regions.

In the IGBT, the semiconductor substrate may have plural n-type pillar layers extending from a position in contact with the emitter electrode to the barrier layer and in Schottky contact with the emitter electrode.

In the IGBT, the semiconductor substrate may have an n-type cathode layer in contact with the collector electrode at a position adjacent to the collector layer.

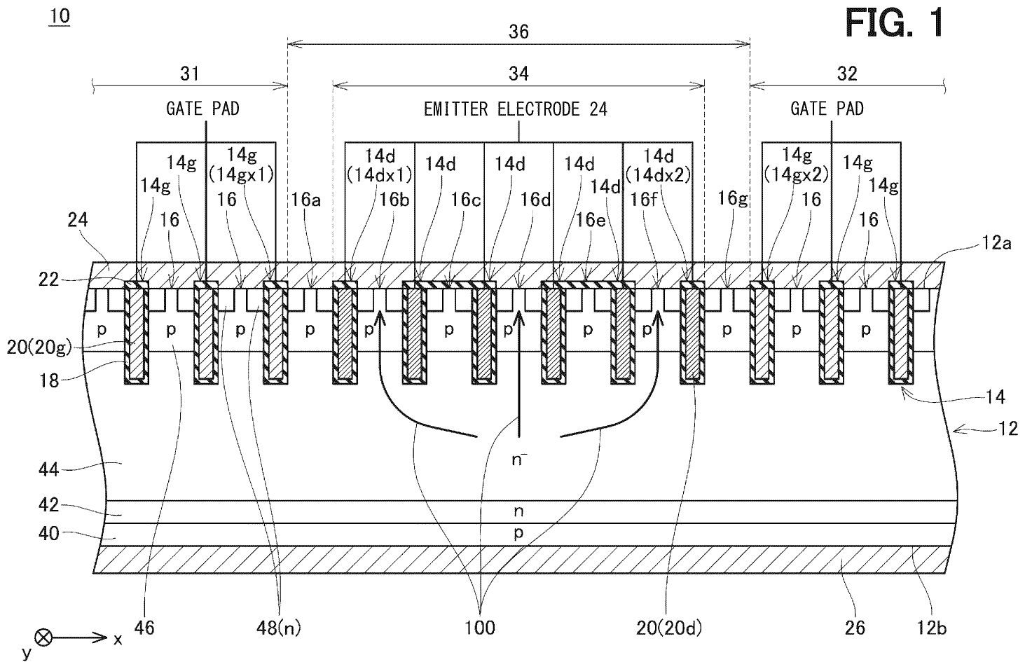

As shown in FIG. 1, an IGBT of the embodiment has a semiconductor substrate 12. In this embodiment, the semiconductor substrate 12 is made of single crystal silicon. However, the semiconductor substrate 12 may be made of other semiconductor materials (for example, SiC, GaN, etc.). Multiple trenches 14 are provided in the upper surface 12a of the semiconductor substrate 12. Each of the trenches 14 extends linearly in the y direction (perpendicular to the paper surface of FIG. 1) on the upper surface 12a. That is, the trenches 14 extend parallel to each other. The trenches 14 are arranged on the upper surface 12a at intervals in the x direction perpendicular to the y direction. Hereinafter, each semiconductor region located between the trenches 14 will be referred to as an inter-trench region 16.

An inner surface of each of the trenches 14 is covered with a gate insulating film 18. A trench electrode 20 is disposed within each of the trenches 14. Each trench electrode 20 is insulated from the semiconductor substrate 12 by a gate insulating film 18.

An interlayer insulating film 22 and an emitter electrode 24 are provided on the upper portion of the semiconductor substrate 12. The interlayer insulating film 22 covers the upper surface of the trench electrode 20. The emitter electrode 24 covers the upper surface 12a of the semiconductor substrate 12 and the interlayer insulating film 22. A collector electrode 26 is provided on the lower portion of the semiconductor substrate 12. The collector electrode 26 covers the lower surface 12b of the semiconductor substrate 12.

The trench electrodes 20 include a gate electrode 20g and a dummy electrode 20d. The gate electrode 20g is insulated from the emitter electrode 24. Therefore, the potential of the gate electrode 20g is independent of the potential of the emitter electrode 24. The gate electrode 20g is connected to a gate pad at a position not shown. The dummy electrode 20d is insulated from the gate electrode 20g. Therefore, the potential of the dummy electrode 20d is independent of the potential of the gate electrode 20g. The dummy electrode 20d is electrically connected to the emitter electrode 24 at a position, for example, an end of the dummy electrode 20d. Therefore, the dummy electrode 20d has the same potential as the emitter electrode 24 (i.e., 0 V). Hereinafter, the trench 14 in which the gate electrode 20g is provided will be referred to as a gate trench 14g, and the trench 14 in which the dummy electrode 20d is provided will be referred to as a dummy trench 14d.

The semiconductor substrate 12 has a first active area 31, a second active area 32, and a non-active area 34. The gate trenches 14g are arranged in the first active area 31. The gate trenches 14g are arranged in the second active area 32. No dummy trenches 14d are arranged in the first active area 31 and the second active area 32. Therefore, each inter-trench region 16 in the first active area 31 and the second active area 32 is disposed between the gate trenches 14g. The non-active area 34 is disposed between the first active area 31 and the second active area 32 in the x direction. The dummy trenches 14d are arranged in the non-active area 34. The gate trench 14g is not disposed in the non-active area 34. Thus, each inter-trench region 16 in the non-active area 34 is disposed between the dummy trenches 14d. Each inter-trench region 16 at the boundary between the active area 31, 32 and the non-active area 34 is disposed between the gate trench 14g and the dummy trench 14d. Hereinafter, the gate trench 14g located the closest to the non-active area 34 among the gate trenches 14g in the first active area 31 will be referred to as a first boundary gate trench 14gx1. Furthermore, among the gate trenches 14g in the second active area 32, the gate trench 14g located the closest to the non-active area 34 is referred to as a second boundary gate trench 14gx2. A region between the first boundary gate trench 14gx1 and the second boundary gate trench 14gx2 is referred to as a hole accumulation region 36. The hole accumulation region 36 includes the non-active area 34. Moreover, the dummy trench 14d adjacent to the first boundary gate trench 14gx1 is referred to as a first boundary dummy trench 14dx1. Moreover, the dummy trench 14d adjacent to the second boundary gate trench 14gx2 is referred to as a second boundary dummy trench 14dx2.

The semiconductor substrate 12 includes a collector layer 40, a buffer layer 42, a drift layer 44, a base layer 46, and plural emitter layers 48.

The collector layer 40 is a p-type layer and is distributed in an area including the lower surface 12b of the semiconductor substrate 12. The collector layer 40 is distributed across the first active area 31, the second active area 32, and the hole accumulation region 36. The collector layer 40 is in ohmic contact with the collector electrode 26 on the lower surface 12b.

The buffer layer 42 is an n-type layer and is disposed on the collector layer 40. The buffer layer 42 is distributed across the first active area 31, the second active area 32, and the hole accumulation region 36. The buffer layer 42 is in contact with the collector layer 40 from the upper side.

The drift layer 44 is an n-type layer having a lower n-type impurity concentration than the buffer layer 42. The drift layer 44 is distributed across the first active area 31, the second active area 32, and the hole accumulation region 36. The drift layer 44 is disposed above the collector layer 40 and the buffer layer 42. The drift layer 44 is in contact with the buffer layer 42 from the upper side. The drift layer 44 is distributed from a position in contact with the buffer layer 42 to a position in contact with the lower end of each trench 14. The drift layer 44 is in contact with the gate insulating film 18 at the bottom and side surfaces of each trench 14. The upper end of the drift layer 44 is located within each of the inter-trench regions 16.

The base layer 46 is a p-type layer and is disposed on the drift layer 44. The base layer 46 is distributed across the first active area 31, the second active area 32, and the hole accumulation region 36. The base layer 46 is disposed within each inter-trench region 16. The base layer 46 is in contact with the drift layer 44 from the upper side. The base layer 46 is in contact with the gate insulating film 18 on the side surface of the trench 14 above the drift layer 44.

Each emitter layer 48 is an n-type layer and is disposed in a corresponding inter-trench region 16. Two emitter layers 48 are disposed within each inter-trench region 16. Each emitter layer 48 is in contact with the gate insulating film 18 at the upper end of each trench 14. Each emitter layer 48 is in contact with the gate insulating film 18 above the base layer 46. Each emitter layer 48 is in contact with the base layer 46. Each emitter layer 48 is separated from the drift layer 44 by the base layer 46. Each emitter layer 48 is disposed in an area that partially includes the upper surface 12a. The base layer 46 is distributed in the area between the two emitter layers 48 in each inter-trench region 16.

The inter-trench regions 16 include a non-contact inter-trench region whose upper surface is covered with the interlayer insulating film 22 and a contact inter-trench region whose upper surface is not covered with the interlayer insulating film 22. In the non-contact inter-trench region, the base layer 46 and the emitter layer 48 are insulated from the emitter electrode 24 by the interlayer insulating film 22. In the contact inter-trench region, the base layer 46 and the emitter layer 48 are in ohmic contact with the emitter electrode 24.

The inter-trench regions 16 in the first active area 31 and the second active area 32 are all the contact inter-trench regions. There are the inter-trench regions 16a to 16g within the hole accumulation region 36. The inter-trench region 16a between the first boundary gate trench 14gx1 and the first boundary dummy trench 14dx1 is the contact inter-trench region. The inter-trench region 16g between the second boundary gate trench 14gx2 and the second boundary dummy trench 14dx2 is the contact inter-trench region. The inter-trench regions 16b to 16f in the non-active area 34 include the contact inter-trench region and the non-contact inter-trench region. The inter-trench region 16b between the first boundary dummy trench 14dx1 and the dummy trench 14d is the contact inter-trench region. The inter-trench region 16c adjacent to the inter-trench region 16b is the non-contact inter-trench region. The inter-trench region 16d adjacent to the inter-trench region 16c is the contact inter-trench region. The inter-trench region 16e adjacent to the inter-trench region 16d is the non-contact inter-trench region. The inter-trench region 16f adjacent to the inter-trench region 16e (i.e., the inter-trench region 16f between the second boundary dummy trench 14dx2 and the dummy trench 14d adjacent thereto) is the contact inter-trench region. In this manner, the non-contact inter-trench regions and the contact inter-trench regions are alternately arranged within the non-active area 34. Therefore, in the hole accumulation region 36, the non-contact inter-trench regions are not adjacent to each other.

Next, the operation of the IGBT 10 will be described. When the IGBT 10 is in operation, a higher potential is applied to the collector electrode 26 than to the emitter electrode 24. The potential of the gate electrode 20g is controlled by a gate control circuit external to the IGBT 10. The potential of the gate electrode 20g is controlled between 0V (that is, the same potential as the emitter electrode 24) and a higher potential. When the potential of the gate electrode 20g is controlled to a potential higher than the gate threshold, a channel is formed in the area of the base layer 46 facing the gate electrode 20g. Since the gate electrode 20g is disposed in the first active area 31 and the second active area 32, a channel is formed in the base layer 46 in the first active area 31 and the second active area 32. The channel connects the emitter layer 48 to the drift layer 44. Since the dummy electrode 20d in the non-active area 34 is electrically connected to the emitter electrode 24, the potential of the dummy electrode 20d is maintained at the potential of the emitter electrode 24. Therefore, no channel is formed in the non-active area 34. When a channel is formed in the first active area 31 and the second active area 32, electrons flow from the emitter layer 48 in the first active area 31 and the second active area 32 through the channel into the drift layer 44. As a result, holes flow from the collector layer 40 through the buffer layer 42 into the drift layer 44. This reduces the resistance of the drift layer 44, allowing electrons to flow through the drift layer 44 with low loss. The electrons in the drift layer 44 flow through the buffer layer 42 to the collector layer. This flow of electrons turns the IGBT on. Furthermore, the holes that have flowed into the drift layer 44 flow to the emitter electrode 24 via the base layer 46. However, since the inter-trench region 16c, 16e is the non-contact inter-trench region, holes do not flow from the base layer 46 to the emitter electrode 24 in the inter-trench region 16c, 16e. For this reason, in the non-active area 34, holes are less likely to flow to the emitter electrode 24 and are more likely to accumulate in the drift layer 44. In this manner, by providing the non-contact inter-trench region in the non-active area 34, holes are easily accumulated in the drift layer 44, and the resistance of the drift layer 44 can be reduced by the IE effect. Therefore, the on-voltage of this IGBT is low.

Thereafter, when the potential of the gate electrode 20g is reduced to 0 V, the channel disappears. Then, the flow of electrons stops and the IGBT 10 turns off. When the IGBT 10 is turned off, the holes present in the drift layer 44 are discharged to the emitter electrode 24 via the base layer 46. If the hole current flowing at this time is concentrated in a specific inter-trench region 16, latch-up occurs.

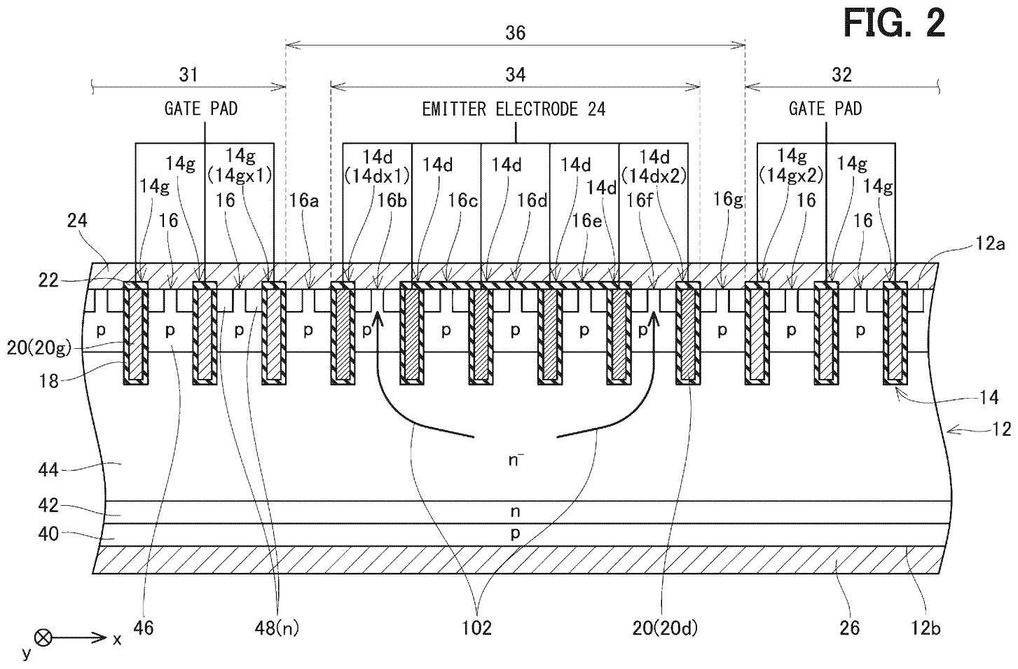

For example, FIG. 2 shows a comparative example in which inter-trench regions 16c to 16e are the non-contact inter-trench regions. In this case, holes accumulated in the drift layer 44 under the inter-trench regions 16c to 16e flow, as indicated by arrows 102, toward the inter-trench region 16b, 16f, which is the contact inter-trench region the closest to the inter-trench regions 16c to 16e. That is, the hole current is concentrated in the inter-trench region 16b, 16f. Then, the potential of the base layer 46 rises in the inter-trench region 16b, 16f, so that holes tend to flow from the base layer 46 into the emitter layer 48 in the inter-trench region 16b, 16f. When the current flows from the base layer 46 to the emitter layer 48, latch-up occurs, causing a high current to flow through the IGBT 10 and placing a high load on the IGBT 10.

In contrast, in the IGBT 10 of FIG. 1, in the hole accumulation region 36 including the non-active area 34, the non-contact inter-trench regions are arranged so as not to be adjacent to each other. Therefore, holes accumulated in the drift layer 44 in the non-active area 34 can flow to the emitter electrode 24 through the contact inter-trench regions (i.e., inter-trench regions 16b, 16d, 16f) adjacent to the non-contact inter-trench regions (i.e., inter-trench regions 16c, 16e), as shown by arrows 100. In this way, in the IGBT 10 of the embodiment, the hole current flows in a dispersed manner when the IGBT 10 is turned off. This makes it possible to restrict the hole current from concentrating in a particular inter-trench region 16, thereby making it possible to suppress latch-up.

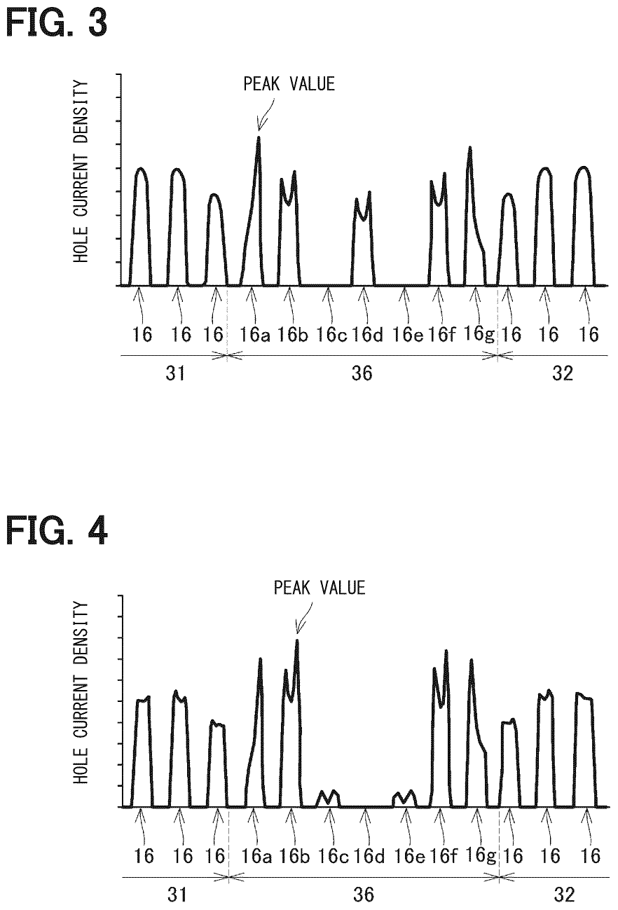

FIG. 3 shows the density distribution of the hole current that flows when the IGBT 10 of the embodiment shown in FIG. 1 is turned off. FIG. 4 shows the density distribution of the hole current that flows when the IGBT of the comparative example shown in FIG. 2 is turned off. As is clear from a comparison between FIGS. 3 and 4, in the IGBT 10 of the embodiment, a hole current flows through the inter-trench region 16d, thereby making it possible to reduce the density of the hole current in the inter-trench region 16b, 16f. This makes it possible to reduce the peak value of the hole current.

As shown in FIG. 3, the density of the hole current is higher in the inter-trench region 16a, 16g than in the other inter-trench regions 16. The inter-trench region 16a, 16g is located between the gate electrode 20g and the dummy electrode 20d. The dummy electrode 20d is fixed to the potential of the emitter electrode 24. On the other hand, at the timing of turn-off, the potential of the gate electrode 20g is close to the gate threshold value. Therefore, at the time of turn-off, the potential of the dummy electrode 20d is lower than the potential of the gate electrode 20g. Therefore, in the inter-trench region 16a, 16g, the hole current tends to flow toward the region close to the dummy electrode 20d, and the density of the hole current tends to become high. Therefore, when holes accumulated in the drift layer 44 in the non-active area 34 flow into the inter-trench region 16a, 16g, the density of the hole current in the inter-trench region 16a, 16g becomes extremely high. In contrast, as shown in FIG. 1, in the IGBT of the embodiment, the inter-trench region 16b, 16f adjacent to the inter-trench region 16a, 16g, in the non-active area 34, is the contact inter-trench region. Therefore, most of the holes accumulated in the drift layer 44 in the non-active area 34 flow into the inter-trench region 16b, 16f, and the concentration of hole current in the inter-trench region 16a, 16g is suppressed. This suppresses latch-up in the inter-trench region 16a, 16g.

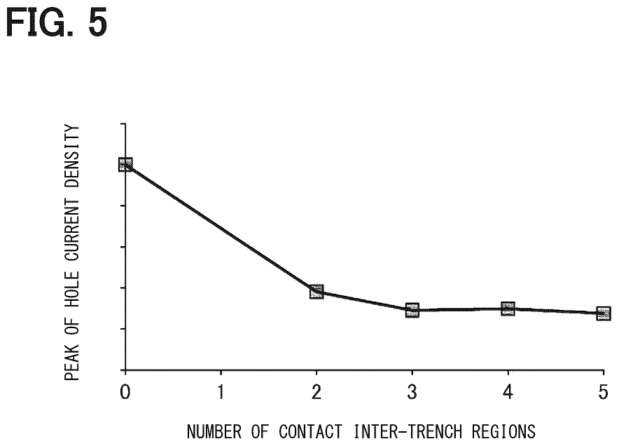

FIG. 5 shows the results of simulating the peak value of the density of the hole current when the number (n) of the contact inter-trench regions, among the inter-trench regions 16b to 16f, is changed. In FIG. 5, the number n=0 indicates a case where all of the inter-trench regions 16b to 16f are the non-contact inter-trench regions. The number n=2 indicates a case corresponding to FIG. 2. The number n=3 indicates a case corresponding to FIG. 1. The number n=4 indicates a case where the inter-trench regions 16b, 16c, 16e, and 16f are the contact inter-trench regions, and the inter-trench region 16d is the non-contact inter-trench region. The number n=5 indicates a case where all of the inter-trench regions 16b to 16f are the contact inter-trench regions. As shown in FIG. 5, when the number n=3, the peak value of the density of the hole current density is lowered to approximately the same extent as when the number n=5. Furthermore, when the number n=2, the peak value of the density of the hole current is higher than when the number n=3.

As described above, according to the IGBT 10 of the embodiment, a low on-voltage can be achieved by the IE effect, and latch-up can be suppressed.

In the embodiment, five inter-trench regions 16 are arranged within the non-active area 34, but the number of inter-trench regions 16 within the non-active area 34 may be more than five or less than five. In the embodiment, the inter-trench region 16a, 16g between the gate trench 14g and the dummy trench 14d is the contact inter-trench region. However, the inter-trench region 16a, 16g between the gate trench 14g and the dummy trench 14d may be the non-contact inter-trench region. In this case as well, latch-up can be suppressed by restricting the non-contact inter-trench regions from being adjacent to each other within the hole accumulation region 36.

In the embodiment, the emitter layer 48 is provided in the non-active area 34, but the emitter layer 48 does not necessarily have to be provided in the non-active area 34.

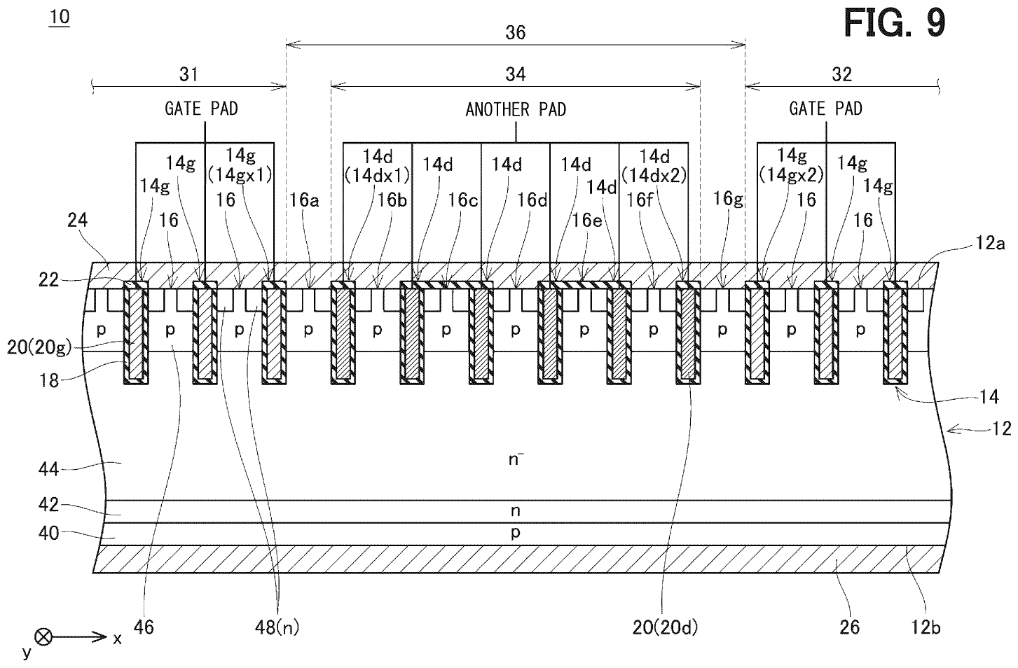

In the embodiment, the dummy electrode 20d is electrically connected to the emitter electrode 24. However, as shown in FIG. 9, if the potential of the dummy electrode 20d is independent of the potential of the gate electrode 20g, the dummy electrode 20d may be electrically connected to another pad other than the emitter electrode 24.

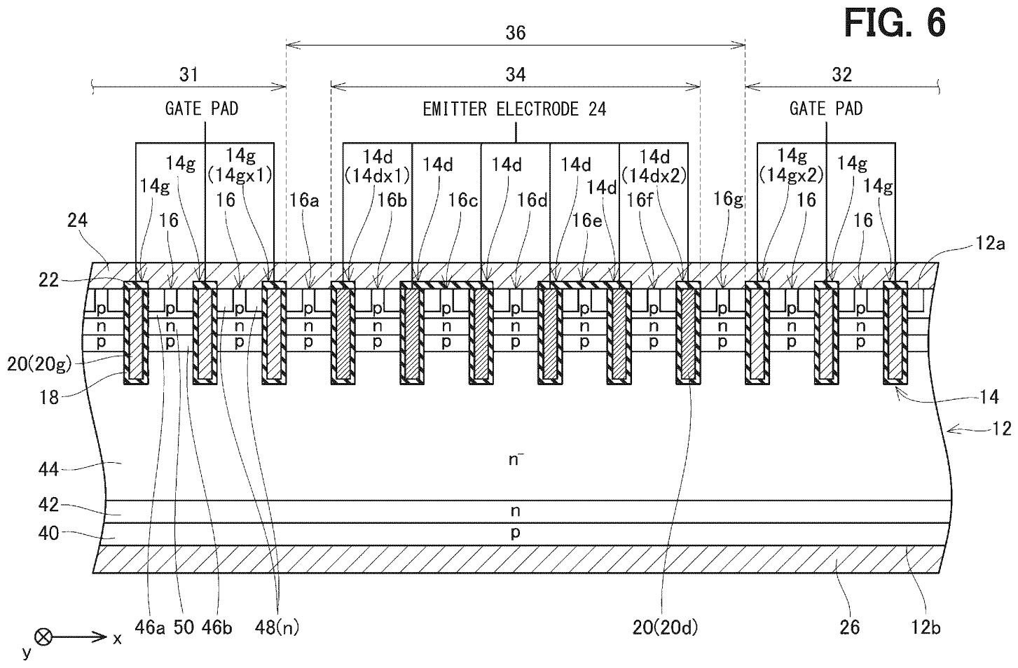

As shown in FIG. 6, an n-type barrier layer 50 may be provided in the base layer 46, and the barrier layer 50 may divide the base layer 46 into an upper base layer 46a and a lower base layer 46b. The upper base layer 46a is distributed across the first active area 31, the second active area 32, and the hole accumulation region 36. The upper base layer 46a is disposed in each of the inter-trench regions 16. The barrier layer 50 is distributed across the first active area 31, the second active area 32, and the hole accumulation region 36. The barrier layer 50 is disposed below the upper base layer 46a. The barrier layer 50 is disposed in each of the inter-trench regions 16. The lower base layer 46b is distributed across the first active area 31, the second active area 32, and the hole accumulation region 36. The lower base layer 46b is disposed between the barrier layer 50 and the drift layer 44. The lower base layer 46b is disposed in each of the inter-trench regions 16. In this configuration, when the IGBT is turned on, holes in the drift layer 44 flow to the emitter electrode 24 through the lower base layer 46b, the barrier layer 50, and the upper base layer 46a. In this configuration, the flow of holes is suppressed by the barrier layer 50, so that holes tend to accumulate in the drift layer 44. Therefore, with this configuration, the on-voltage of the IGBT can be further reduced.

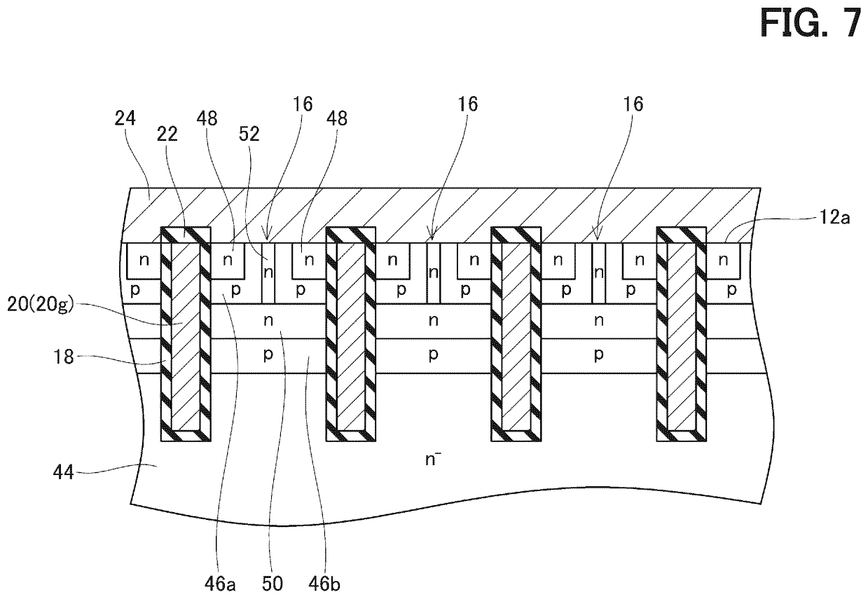

When the barrier layer 50 is provided, as shown in FIG. 7, plural n-type pillar layers 52 may be provided. Each pillar layer 52 is disposed within a corresponding inter-trench region 16. Each pillar layer 52 extends from a position in contact with the emitter electrode 24 to the barrier layer 50. Each pillar layer 52 is in Schottky contact with the emitter electrode 24. According to this configuration, the on-voltage of the IGBT can be reduced more effectively.

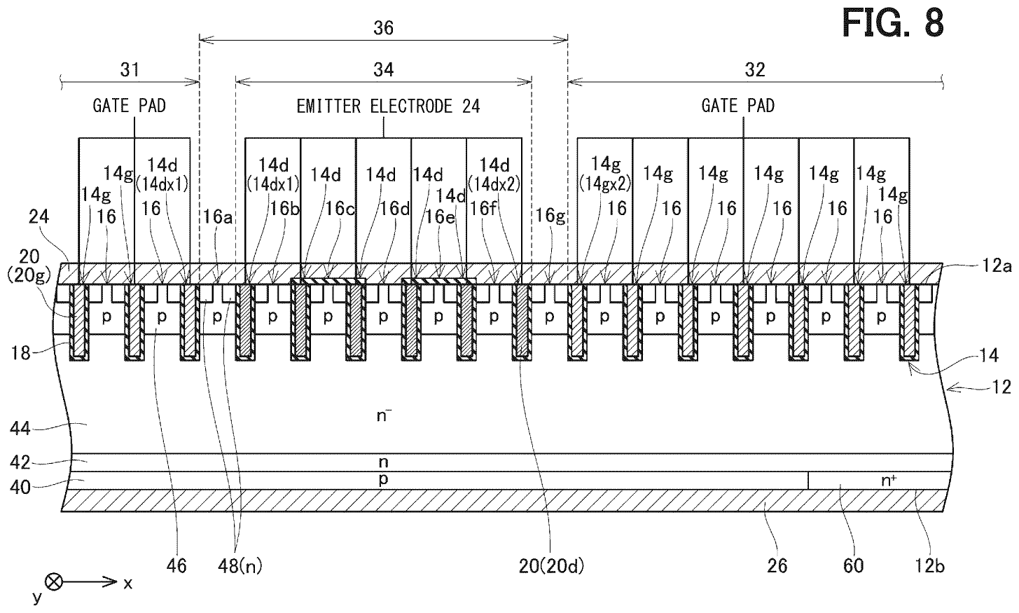

As shown in FIG. 8, an n-type cathode layer 60 may be provided in the semiconductor substrate 12. The cathode layer 60 is disposed below the buffer layer 42. The n-type impurity concentration of the cathode layer 60 is higher than the n-type impurity concentration of the buffer layer 42. The cathode layer 60 is in ohmic contact with the collector electrode 26 at a position adjacent to the collector layer 40. According to this configuration, a pn diode is formed between the emitter electrode 24 and the collector electrode 26 by the base layer 46, the drift layer 44, the buffer layer 42, and the cathode layer 60. The pn diode can function as a so-called freewheeling diode, and turns on when a potential higher than that of the collector electrode 26 is applied to the emitter electrode 24.

Although the embodiments have been described in detail above, these are merely examples and do not limit the scope of claims. The techniques described in claims include various modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve a plurality of objectives at the same time, and achieving one of the objectives itself has technical usefulness.

What is claimed is:

1. An insulated gate bipolar transistor comprising:
a semiconductor substrate having a plurality of trenches spaced with each other in an upper surface of the semiconductor substrate;
an emitter electrode provided on the upper surface of the semiconductor substrate;
a collector electrode provided on a lower surface of the semiconductor substrate;
a gate insulating film covering an inner surface of each of the trenches; and
a trench electrode disposed in each of the trenches and insulated from the semiconductor substrate by the gate insulating film, wherein
the plurality of trenches includes a gate trench and a dummy trench,
the trench electrode in the gate trench is a gate electrode having a potential independent of the emitter electrode,
the trench electrode in the dummy trench is a dummy electrode having a potential independent of the gate electrode,
the semiconductor substrate includes:
a first active area in which the gate trench is one of a plurality of gate trenches;
a second active area in which the gate trench is one of a plurality of gate trenches; and
a non-active area positioned between the first active area and the second active area, the non-active area having the dummy trench that is one of a plurality of dummy trenches,
the semiconductor substrate includes:
a p-type collector layer in contact with the collector electrode and distributed across the first active area, the second active area, and the non-active area;
an n-type drift layer disposed above the collector layer and distributed across the first active area, the second active area, and the non-active area;
a p-type base layer disposed in an inter-trench region located between the trenches, above the drift layer, and distributed across the first active area, the second active area, and the non-active area; and
a plurality of n-type emitter layers disposed in the inter-trench region of the first active area and the second active area, in contact with the gate insulating film, in contact with the emitter electrode, and separated from the drift layer by the base layer,
the base layer is in contact with the emitter electrode, in the inter-trench region of the first active area and the second active area, and
the inter-trench region is arranged in a hole accumulation region between a first boundary gate trench that is the gate trench of the first active area located the closest to the non-active area and a second boundary gate trench that is the gate trench of the second active area located the closest to the non-active area so as to satisfy following conditions:
(i) a plurality of non-contact inter-trench regions are disposed within the non-active area, the non-contact inter-trench region being the inter-trench region in which the base layer is insulated from the emitter electrode;
(ii) at least one contact inter-trench region is disposed within the non-active area, the contact inter-trench region being the inter-trench region in which the base layer is in contact with the emitter electrode; and
(iii) the non-contact inter-trench regions are not adjacent to each other in the hole accumulation region.

2. The insulated gate bipolar transistor according to claim 1, wherein
the dummy trench adjacent to the first boundary gate trench is defined as a first boundary dummy trench,
the inter-trench region between the first boundary gate trench and the first boundary dummy trench is the contact inter-trench region,
the inter-trench region between the first boundary dummy trench and the dummy trench adjacent to each other is the contact inter-trench region,
the dummy trench adjacent to the second boundary gate trench is defined as a second boundary dummy trench,
the inter-trench region between the second boundary gate trench and the second boundary dummy trench is the contact inter-trench region, and
the inter-trench region between the second boundary dummy trench and the dummy trench adjacent to each other is the contact inter-trench region.

3. The insulated gate bipolar transistor according to claim 1, wherein
the semiconductor substrate includes:
an n-type barrier layer disposed within the inter-trench region, below the base layer, and distributed across the first active area, the second active area, and the non-active area; and
a p-type lower base layer disposed within the inter-trench region, located between the barrier layer and the drift layer, and distributed across the first active area, the second active area, and the non-active area.

4. The insulated gate bipolar transistor according to claim 3, wherein
the semiconductor substrate has a plurality of n-type pillar layers extending from a position in contact with the emitter electrode to the barrier layer, and
the plurality of n-type pillar layers is in Schottky contact with the emitter electrode.

5. The insulated gate bipolar transistor according to claim 1, wherein
the semiconductor substrate has an n-type cathode layer in contact with the collector electrode at a position adjacent to the collector layer.

6. The insulated gate bipolar transistor according to claim 1, wherein
the collector layer is continuously distributed from the first active area through the hole accumulation region to the second active area, and
the inter-trench region is arranged in the hole accumulation region so as to satisfy the conditions within an area where the collector layer is continuously distributed from the first active area through the hole accumulation region to the second active area.

7. The insulated gate bipolar transistor according to claim 6, wherein
the collector layer is located directly below an area where the base layer is in contact with the emitter electrode within the contact inter-trench region.
